(19) United States
(12) Patent Application Publication
(10) Pub. No.: US 2007/0001542 A1
(43) Pub. Date: Jan. 4, 2007

(54) Versatile system for restricting movement of MEMS structures

(76) Inventor: Jason Michael Neidrich, Fairview, TX (US)

Correspondence Address: TEXAS INSTRUMENTS INCORPORATED, P O BOX 655474, M/S 3999, DALLAS, TX, 75265, US

(21) Appl. No.: 11/172,348

(22) Filed: Jun. 30, 2005

(51) Int. Cl. H01L 21/00; H02N 1/00

(52) U.S. Cl. 310/309; 359/291

(57) ABSTRACT

The present invention provides a system for selectively restricting movement of a MEMS device (200). The system of the present invention provides a device comprising movable MEMS device structure (222) and a fixed gate structure (218). A latch structure (248) is formed or otherwise disposed along the MEMS device structure, in proximity to the gate structure. A locking electrode (212) is disposed or formed in proximity to the gate structure, and is adapted to force the latch structure into engagement with the gate structure responsive to an activation signal. Circuitry (202) provides the activation signal to the locking electrode.

### TECHNICAL FIELD OF THE INVENTION

The present invention relates generally to the field of micro-electromechanical systems (MEMS) and, more particularly, to a versatile system of apparatus and methods for locking or otherwise selectively restricting the movement of certain MEMS structures.

### BACKGROUND OF THE INVENTION

The continual demand for enhanced speed, capacity and efficiency has resulted in dramatic advances in a variety of manufacturing fields (e.g., electronics, communications, machinery). Among many recent developments, the field of electro-mechanics has focused significant attention on the miniaturization of various devices. A micro-electromechanical system (MEMS) is usually a system that has electrically controllable micro-machines (such as a motor, gear, optical modulating element, etc.) formed monolithically on a semiconductor substrate using integrated circuit techniques.

A number of MEMS devices have operational elements—utilizing complex, multi-layer metal structures—formed directly atop operational circuitry layers. Thus, depending upon the operational characteristics of a specific device, an operational element may be moved or deformed by electrostatic or electromechanical forces generated by the circuitry.

This direct interface between circuitry and operational MEMS structures can sometimes cause operational problems, depending upon the function of a device or specific operational elements within a device. In a number of applications, for example, it may be necessary to restrict electrostatic movement of one operational element while electrostatically actuating an immediately adjacent operational element. Given the minute scale of such structures and the separations therebetween, electrostatic signals—whether actuating or restricting—or their related electromagnetic effects can adversely affect the movement of both operational elements, leading to device malfunctions or performance losses. Brute force solutions (e.g., complex routing layouts, elaborate operational schemes) might be employed to overcome such a problem, but will introduce a number of inefficiencies to device manufacturing or operation—increasing costs or reducing performance.

Some conventional systems have relied on the introduction of certain chemical formulations (e.g., lubricants) onto critical surfaces of a MEMS device, in order to provide stiction-induced movement restriction. Generally, such schemes rely on physical reactions or interactions, such as surface tension between formulations, to hold operational elements in place until those operational elements are directly actuated.

Depending upon the nature of a MEMS device, or upon the nature of chemical formulations used, such a scheme may be of limited effectiveness. Where aberrant electrostatic or electromagnetic forces are substantial or continuous, those forces may be sufficient to overcome a chemically induced stiction—causing an unintended actuation of an operational element. Even where stiction-induced restriction is not overcome, other considerations may militate against chemical formulation approaches. The process of applying such formulations, whether on a generalized or selective basis, adds a certain amount of overhead to manufacturing processes. Selective masking, application, and cleaning processes introduce additional material and labor costs, and provide increased opportunities for yield loss due to contamination or handling. Furthermore, a number of stiction suitable chemical formulations—that are otherwise viable or compatible with semiconductor manufacturing processes—may present certain environmental or regulatory concerns. The use of a potentially toxic or hazardous compound in a MEMS device intended for a consumer product usage may require certain regulatory compliance measures—increasing production costs—or result in an undesirable product reputation.

As a result, there is a need for a system that provides reliable and accurate restriction of MEMS device structure movement, without relying on continuous electrostatic or electromagnetic force or on chemically induced stiction—one that is readily adaptable to a number of production or manufacturing processes, and to address a variety of specific design requirements—while providing reliable device performance in an easy, efficient and cost-effective manner.

### SUMMARY OF THE INVENTION

The present invention provides a versatile system, comprising various apparatus and methods, for reliably and accurately restricting the movement of discrete MEMS structures. The system of the present invention restricts MEMS structure movement without relying on continuous electrostatic or electromagnetic forces, or on chemically induced stiction locks. The system of the present invention is a secure MEMS locking system that is readily and easily adaptable to a number of device applications, design requirements, and production or manufacturing processes. The system of the present invention obviates unintended MEMS movements due to electric and other physical forces—providing reliable device performance in an easy, efficient and cost-effective manner.

Specifically, the present invention provides a physical MEMS locking or restrictive mechanism that is readily fabricated within existing semiconductor technologies. This locking mechanism of the present invention is fabricated such that, once device production is completed, a metal latch member is disposed in proximity to one or more gate members. A locking signal provides an electrostatic charge that pulls the latch member past the gate member(s) and into a restricted, or locked, position. The system of the present invention may be provided such that this locking process may be done only once (e.g., post-assembly test), or may be done dynamically during device operation (e.g., using specific addressing schemes).

More specifically, embodiments of the present invention provide variations of a system for selectively restricting movement of a MEMS device. The system of the present invention provides a MEMS device comprising movable device structure and a fixed gate structure. A latch structure is formed or otherwise disposed along the MEMS device structure, in proximity to the fixed gate structure. A locking signal element (e.g., electrode) is disposed or formed in proximity to the fixed gate structure. The locking signal element is adapted to force the latch structure into engagement with the gate structure, responsive to an activation signal provided by circuitry within the MEMS device.

Other features and advantages of the present invention will be apparent to those of ordinary skill in the art upon reference to the following detailed description taken in conjunction with the accompanying drawings.

### BRIEF DESCRIPTION OF THE DRAWINGS

For a better understanding of the invention, and to show by way of example how the same may be carried into effect, reference is now made to the detailed description of the invention along with the accompanying figures in which corresponding numerals in the different figures refer to corresponding parts and in which:

FIG. 1 provides an illustration depicting one embodiment of a MEMS device;

FIG. 2 provides an illustration depicting one embodiment of a MEMS structure in accordance with certain aspects of the present invention; and

FIG. 3 provides another illustration depicting one embodiment of a MEMS structure in accordance with certain aspects of the present invention.

### DETAILED DESCRIPTION OF THE INVENTION

While the making and using of various embodiments of the present invention are discussed in detail below, it should be appreciated that the present invention provides many applicable inventive concepts, which can be embodied in a wide variety of specific contexts. Although certain aspects of the present invention may be described in relation to specific techniques or structures, the teachings and principles of the present invention are not limited solely to such examples. The specific embodiments discussed herein are merely demonstrative of specific ways to make and use the invention and do not limit the scope of the invention.

For purposes of explanation and illustration, certain aspects of the present invention are hereafter illustratively described in conjunction with the design and production of various embodiments of locking or restrictive structures within a particular type of MEMS device. Although described in relation to such structure and such a device, it should be understood and apparent that the present invention may be readily implemented in numerous MEMS structures and applications.

Although MEMS devices may be produced for a number of general or specialized applications, most currently available MEMS devices are—to some degree—application specific. Consider, for example, a digital micro-mirror device (DMD™) developed by Texas Instruments Incorporated. The DMD is a spatial light modulation (SLM) device, used to modulate incident light in a spatial pattern to form an image corresponding to an electrical or optical input. A DMD is a monolithic single chip circuit—having a high-density array of moveable micromirrors fabricated, using CMOS processes, over CMOS address circuitry.

A DMD has an array of individually addressable mirror elements, each having an aluminum mirror that can reflect light in one of two directions depending on the state of an underlying memory cell. By combining the DMD with a suitable light source and projection optics, the mirror reflects incident light either into or out of the pupil of the projection lens. Thus, one state of the mirror appears bright and a second state of the mirror appears dark. Gray scale is achieved by binary pulse width modulation of the incident light. Color is achieved by using color filters—either stationary or rotating—in combination with one, two, or three DMD chips.

The design and fabrication of DMDs has evolved over the years. Early DMD spatial light modulators implemented a deflectable mirror/beam. An electrostatic force was created between the mirror and the underlying address electrode to induce deflection of the mirror. The mirror was supported by torsion hinges and axially rotated one of two directions. In the bi-stable mode, the mirror tips landed upon a landing pad. The following patents describe this first generation of DMDs: U.S. Pat. No. 4,662,746; U.S. Pat. Nos. 4,710,732; 4,956,619; and U.S. Pat. No. 5,172,262.

More recent DMD devices have mirrors that are supported above a lateral support platen or platform—often referred to as a beam or a yoke. A yoke/mirror structure is suspended over addressing circuitry by torsion hinges. An electrostatic force developed between an underlying memory cell and a yoke/mirror structure causes rotation of the mirror in a positive or negative direction. The yoke/mirror structure rotates until small spring-tip protrusions along the outer perimeter of the yoke come into contact with a landing electrode. The following patents describe these DMDs in greater detail: U.S. Pat. No. 5,083,857; U.S. Pat. No. 5,600,383; and U.S. Pat. No. 5,535,047.

Generally, the fabrication of recent DMD devices begins with a completed CMOS memory circuit. Once fabrication of the CMOS circuitry is substantially complete, the same fabrication processes are utilized to form a DMD superstructure directly atop the CMOS circuitry. Through the use of, for example, photolithography techniques, a DMD superstructure is formed from alternating layers of metal (e.g., aluminum) for the address electrode, hinge, yoke, and mirror layers.

Certain techniques for fabricating DMD structures involve the selective deposition of one or more metal layers on top of one or more sacrificial layers. Such sacrificial layers often comprise a solvent/resin solution, such as photoresist. After the metal layers have been patterned and etched in a desired manner, then the sacrificial layers are removed—uncovering a freestanding micromirror structure. This is often referred to as undercutting the micromirror structure.

More detailed discussions of a DMD device and its use may be found in the following patents: U.S. Pat. No. 5,061,049; U.S. Pat. No. 5,079,544; U.S. Pat. No. 5,105,369; and U.S. Pat. No. 5,278,652. Each of these patents is assigned to Texas Instruments Incorporated.

In a number of DMD architectures, an array of micromirrors may be formed—due to various manufacturing and economic considerations—of larger dimension than is needed during operation of the DMD device. Thus, from an (N×M) fabricated array, an operational “active” area may comprise some smaller (A×B) sub-array within the center of the (N×M) array. There may be a number of reasons for using some sub-portion of the (N×M) array, such as ensuring that a utilized smaller (A×B) sub-array has optimal uniformity characteristics or a lower number of surface defects. In such sub-array applications, it may be necessary or desirable to “black out” or otherwise disable certain mirror structures within the (N×M) array that lie outside of the operable (A×B) array area.

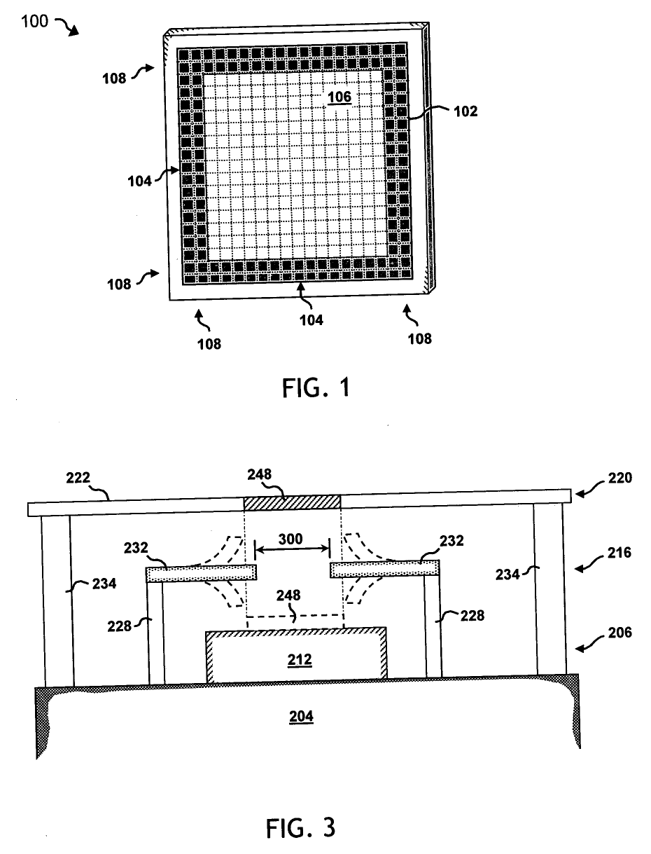

This is illustrated now with reference to FIG. 1, where a DMD device segment 100 comprises a primary array 102 of micromirror elements 104. During operation of segment 100, only the micromirror elements in active area sub-array 106 are required or desired. Thus, inactive micromirror elements 108 remaining in array 102—especially those in immediate proximity to array 106, must be somehow deactivated, so as not to produce device malfunctions or errors (e.g., twinkling pixels). This is readily achieved by positioning each element 108 in a deflected orientation—such that it cannot cause a device malfunction or error. Once an element 108 is so positioned, however, it must be held in that position for an indefinite amount of time during either the operation or the lifetime of device 100.

Comprehending this and other similar MEMS considerations, the present invention provides a system that reliably and accurately restricts the movement of a micromirror element—and more generally, a discrete MEMS structure—on a permanent, temporary or dynamic basis. Unlike certain conventional approaches, the system of the present invention restricts structural movement without relying upon continuous electrostatic or electromagnetic forces, or upon chemically induced stiction locks.

The present invention provides a secure MEMS locking system that is readily and easily adaptable to a number of device applications, design requirements, and production or manufacturing processes. This MEMS locking system obviates unintended MEMS movements due to electric and other physical forces. According to the present invention, a physical MEMS locking mechanism is provided, in such a manner that it may be readily fabricated within wide range of existing and yet-to-be-developed semiconductor technologies.

This locking mechanism is fabricated such that a latch member or structure is disposed along a movable or deformable structure. The latch structure is oriented in proximity to one or more gate structures or members. Once device production is complete, the locking mechanism may be activated or deactivated one or more times, depending upon specific design or performance requirements. An activation signal is processed through a locking signal element to provide a temporary electrostatic or electromagnetic charge that causes a latch member to engage with (e.g., hold to or move past) a gate structure—into a locked or restricted position. Once the latch member is in this position, the activation signal may be terminated. In applications where it may be desirable or necessary to have the locking mechanism lock and unlock, either on an intermittent or regular basis, a deactivation signal (e.g., a separate signal, a reverse-polarity activation signal) provides a temporary electrostatic charge that causes the latch member to disengage from the gate structure into an unlocked position. The present invention thus provides a locking process that may be done only once (e.g., post-assembly test), or may be done dynamically during device operation (e.g., using specific addressing schemes).

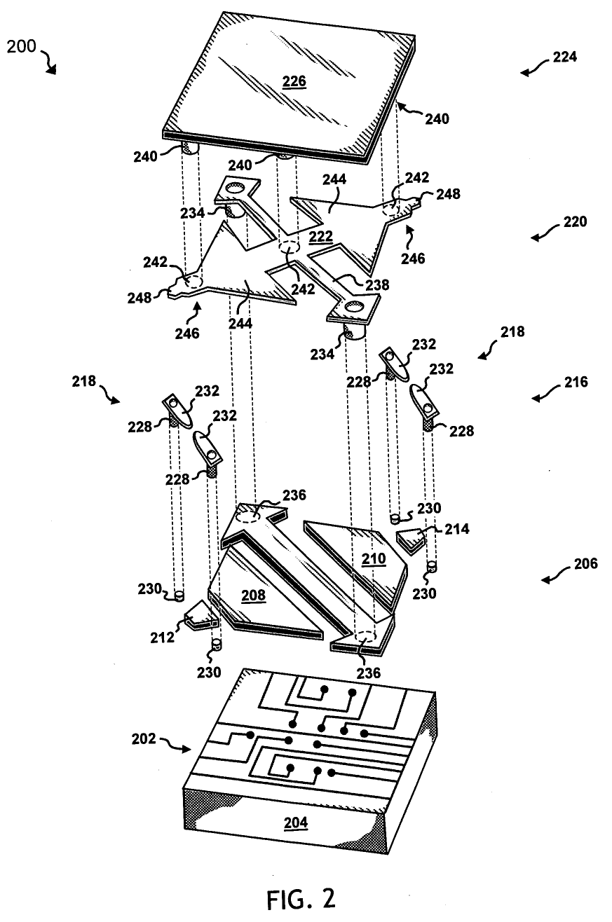

Certain aspects of the present invention are described in greater detail now with reference to FIG. 2, which illustratively depicts a MEMS component 200 according to the present invention. In this particular example, the MEMS component illustrated represents a single micromirror element. Component 200 comprises several structural levels formed atop CMOS circuitry 202, which is fabricated along a substrate 204. Circuitry 202 may comprise circuitry dedicated solely to the operation of component 200, or may comprise other circuitry routed through or around circuitry for the operation of component 200.

Atop circuitry 202 is formed a MEMS foundation or base layer 206. In this embodiment, layer 206 comprises a metallization layer along which numerous electrodes may be formed. Opposing operational electrodes 208 and 210 may be formed along layer 206. Layer 206 further comprises opposing locking signal elements 212 and 214. In the embodiment depicted, elements 212 and 214 also comprise electrodes. An intermediary structural level 216 is formed, comprising one or more gate elements 218. An upper structural layer 220 is formed, comprising a beam or yoke structure 222. Structure 222 is designed or formed to support the operational layer 224, which comprises a single micromirror element 226.

Operationally, the electrodes of layer 206 are coupled to circuitry 202 to provided selective operation of component 200 in accordance with the present invention. A gate element 218 has some support or foundation portion 228 that is formed as part of or disposed atop some gate base 230 within layer 206. Each support portion 228 is formed of sufficient dimension or form factor to support a gate member 232 of each element 218, and to provide operable clearance between layer 206 and a gate member 232.

Structure 222 comprises two support or foundation portions 234 that are formed as part of or disposed atop some base sites 236 within layer 206. Support portions 234 may be formed as inter-level vias or any other suitable structure. Portions 234 are positioned along a central axial or hinge portion 238 of structure 222—particularly at opposite ends thereof. During the operation of component 200, element 226 may be manipulated, via circuitry 202, to axially deflect in a direction orthogonal to portion 238.

Layer 224 further comprises one or more support or foundation portions 240 that are formed as part of or disposed atop some support site(s) 242 along structure 222. Portions 240 may be formed as inter-level vias, or any other suitable structure. In component 200, portions 240 secure element 226 to structure 222 along a yoke portion 244 of structure 222 that is formed orthogonal to hinge portion 238.

Each open end of portion 244 terminates a tip area 246. Each tip area 246 may terminate in a latch element 248. A latch element 248 is manipulated—through operation of component 200—such that it may be cooperatively engaged with a gate element 218 to physically restrain or restrict the movement of structure 220, and thereby the position of element 226, as explained in greater detail hereafter.

Referring now to FIG. 3, a partial side-view of component 200 is depicted to illustrate certain operational aspects in accordance with the present invention. In this embodiment, gate members 232 comprise rigid or semi-rigid splines that extend from their respective supports 228 outwardly over electrode 212, leaving an opening 300 of some desired dimension therebetween. Latch element 248 is formed of a dimension slightly greater than that of opening 300. When—whether on a permanent or temporary basis—it is desirable to lock component 200 into a deflected position in the direction of element 212, an appropriate activation signal or electric charge is initiated within element 212 by circuitry 202. That charge is of sufficient strength to attract latch element 248 and pull it through opening 300 (i.e., past gate members 232). Depending upon various design constraints or desires (e.g., materials available, design dimensions), the charge initiated within electrode 212 may also cause some partial downward deflection of the gate members 232 to temporarily alter the dimension of opening 300—providing easier passage of latch element 248.

Once latch element 248 has been brought past opening 300 into a locked or restricted position, the activation signal or charge may be terminated. The locking structure of the present invention does not require a continues electrostatic or electromagnetic charge to restrict movement. The composition, design or positioning of members 232 and element 248 are provided such that—in the absence of the activation signal—element 248 is physically confined below members 232. For example, members 232 may be formed of metal with sufficient rigidity to indefinitely constrain element 248. Such members 232 may be formed of sufficient strength to do so even while withstanding incidental mechanical forces (e.g., component movement, jarring) and minor electromechanical forces (e.g., unrelated signals passing through circuitry 202). This confinement by member 232, in turn, restricts the respective end of structure 222 to a fixed position oriented toward element 212. This, consequently, restricts mirror element 226 to a fixed, desired position—effectively locking it into place.

In certain embodiments, where locking or restriction of a MEMS component is dynamic or temporary, it may be desirable to unlock component 200. In such embodiments, an appropriate deactivation signal or electric charge (e.g., a charge of reverse polarity to an activation signal) is initiated within element 212 by circuitry 202. That charge is of sufficient strength to repel latch element 248 and push it through opening 300 (i.e., past gate members 232). Depending upon various design constraints or desires (e.g., materials available, design dimensions), the charge initiated within electrode 212 may also cause some partial upward deflection of the gate members 232 to temporarily alter the dimension of opening 300—providing easier passage of latch element 248. Once latch element 248 has been freed from beneath opening 300, the deactivation signal or charge may be terminated. Subsequently, mirror element 226 may be operated without restriction.

In certain alternative embodiments, it may be desirable to lock component 200 into a deflected position in the direction of element 214. Similar to locking component 200 in the direction of element 212, an appropriate activation signal or electric charge is initiated within element 214 by circuitry 202. That charge is of sufficient strength to attract the respective latch element and pull it through the respective opening of the gate element 218 on that side. If component 200 starts from an unlocked, operational position, then this locking sequence would proceed similar to the locking of component 200 in the direction of element 212, as described above. If, however, component 200 starts from a position where it is already locked in the direction of element 212, then it must be unlocked from that position before it can be locked in the direction of element 214. This may be accomplished by sequentially unlocking structure 222 from the side of element 212, and then locking structure 222 in the direction of element 214, or by concurrently providing a deactivation signal at element 212 and an activation signal at element 214. The system of the present invention thus provides temporary or dynamic locking, or movement restriction, in addition to fixed locking.

In certain embodiments, the design, composition and layout of component 200 may be provided such that electrodes 212 or 214 are capable of projecting sufficient activation force (e.g., electrostatic or electromagnetic) to attract and pull, or repel and push, a latch element 248—and thus move structure 222—without assistance. In other alternative embodiments, it may be desirable or necessary to operate electrodes 208 and 210 in conjunction with electrodes 212 and 214, respectively. Electrode 208 may be operated to shift structure 222 into a position where latch element 248 is in immediate proximity to gate element 218. Electrode 212 then only needs to projecting sufficient activation force to pull latch element 248 past gate members 232—rather than projecting activation force sufficient to move structure 222 and secure latch 248. In other alternative embodiments, a locking signal element or electrode may be integrated, either physically or functionally, with a single operational electrode. In such an embodiment for example, this single electrode may project sufficient force during normal operation of component 200 to merely move mirror element 226 between a deflected or non-deflected position, without locking. If a locking of the mirror is desired, then this single electrode is operated to project additional force sufficient to initiate locking in accordance with the present invention. Thus, a number of design form factors and operational schemes may be addressed.

The present invention further comprehends a number of variations and adaptations depending upon specific MEMS design or operational requirements. As stated above, the present invention is readily adaptable not only to DMD applications, but also to a wide range of MEMS devices and systems. The system of the present invention is readily implemented in high-volume commercial semiconductor fabrication processes. The gate and latch members or components of the present invention may be produced using conventional lithography and deposition techniques. The system of the present invention may also be implemented in MEMS fabrication using non-semiconductor or more conventional mechanical processes. The gate and latch members of the present invention may be produced using any suitable process (e.g., casting, extrusion, machining) capable of forming them. Although the present invention obviates the need, the system of the present invention may further be utilized in conjunction with chemically induced stiction locking where desired.

A number of variations in the construction and composition of the gate and latch members are also comprehended. Although discrete gate elements are illustrated above as a pair of opposing splines, gate members according to the present invention may comprise single or multiple structures, and may be formed of any necessary or desired shape. For example, in certain embodiments, a gate member may comprise a single, flange-like element projecting orthogonally from vertical surface. A latch member may comprise a tab or post designed to lock by engaging with or moving past the flange. Any suitable shape, orientation or configuration may be utilized in accordance with the present invention.

The embodiments and examples set forth herein are therefore presented to best explain the present invention and its practical application, and to thereby enable those skilled in the art to make and utilize the invention. However, those skilled in the art will recognize from the foregoing description and examples that the present invention comprehends a number of variations and alterations. For example, certain aspects of the present invention have been described above in relation to the formation of planar structures. The principles and teachings of the present invention are, however, also applicable to non-planar MEMS structures (e.g., parallel curved structures, concentric conduit or column structures). Furthermore, although described in relation to a DMD device, the present invention is equally applicable to other types of MEMS devices (e.g., micro-motors, micro-fluidic devices). The description as set forth herein is therefore not intended to be exhaustive or to limit the invention to the precise form disclosed. As stated throughout, many modifications and variations are possible in light of the above teaching without departing from the spirit and scope of the following claims.

What is claimed is:

1. A micro-electromechanical device comprising:
a movable first structure;
a gate structure;
a latch structure, disposed along the movable first structure in proximity to the gate structure; and
a locking signal element, adapted to force the latch structure into engagement with the gate structure.

2. The device of claim 1, wherein the micro-electromechanical device comprises a digital micromirror device.

3. The device of claim 1, wherein the movable first, gate and latch structures are planar.

4. The device of claim 1, wherein the movable first, gate and latch structures are formed of metal.

5. The device of claim 1, further comprising a plurality of gate structures.

6. The device of claim 1, wherein the gate structure comprises a plurality of gate elements.

7. The device of claim 1, wherein the gate structure comprises a spline.

8. The device of claim 1, wherein the gate structure is interposed between the movable first structure and the locking signal element.

9. The device of claim 1, wherein the locking signal element comprises an electrode.

10. The device of claim 1, wherein the locking signal element is adapted to supply force sufficient to move the movable first structure force and to force the latch structure into engagement with gate structure.

11. The device of claim 1, wherein the locking signal element is adapted to supply force sufficient only to force the latch structure into engagement with gate structure.

12. A method of restricting movement of a movable micro-electromechanical device structure, the method comprising the steps of:
providing a first movable micro-electromechanical device structure;
providing a gate structure;
providing a latch structure, disposed along the first movable micro-electromechanical device structure in proximity to the gate structure;
providing a locking signal element, adapted to force the latch structure into engagement with the gate structure responsive to an activation signal;
providing the activation signal to force the latch structure into engagement with the gate structure; and
terminating the activation signal.

13. The method of claim 12, wherein the step of providing a locking signal element further comprises providing a locking signal element adapted to force the latch structure into engagement with the gate structure responsive to an activation signal, and to free the latch structure from engagement with the gate structure responsive to a deactivation signal.

14. The method of claim 12, wherein the step of providing a first movable micro-electromechanical device structure further comprises providing a digital micromirror device structure.

15. The method of claim 12, wherein the step of providing a first movable micro-electromechanical device structure further comprises producing a first movable micro-electromechanical device structure using semiconductor fabrication processes.

16. The method of claim 12, wherein the step of providing a gate structure further comprises producing a gate structure using semiconductor fabrication processes.

17. The method of claim 12, wherein the step of providing a latch structure further comprises producing a latch structure using semiconductor fabrication processes.

18. The method of claim 12, wherein the step of providing a locking signal element further comprises producing a locking signal element using semiconductor fabrication processes.

19. The method of claim 12, wherein the step of providing the activation signal to force the latch structure into engagement with the gate structure further comprises providing the activation signal only once.

20. The method of claim 12, wherein the step of providing the activation signal to force the latch structure into engagement with the gate structure further comprises providing the activation signal more than once.

21. A system for selectively restricting movement of a MEMS device structure, the system comprising:
a movable MEMS device structure;
a fixed gate structure;
a latch structure, formed or disposed along the movable MEMS structure in proximity to the fixed gate structure;
a locking electrode, adapted to force the latch structure into engagement with the fixed gate structure responsive to an activation signal, and to free the latch structure from engagement with the fixed gate structure responsive to a deactivation signal; and
circuitry to provide the activation or deactivation signal to the locking electrode.
